(19) United States
(12) Patent Application Publication
(10) Pub. No.: US 2014/0261621 A1
(43) Pub. Date: Sep. 18, 2014

(54) WINDOW SOLAR HARVESTING MEANS

(71) Applicant: Qualcomm Mems Technologies, Inc., San Diego, CA (US)

(72) Inventors: Russell Gruhlke, Milpitas, CA (US); Fan Yang, Sunnyvale, CA (US); Ying Zhou, Milpitas, CA (US); Sijin Han, Milpitas, CA (US)

(21) Appl. No.: 13/828,083

(22) Filed: Mar. 14, 2013

(51) Int. Cl. H01L 31/052; H01L 31/18

(52) U.S. Cl. CPC H01L 31/0524; H01L 31/18
USPC 136/246; 136/259; 29/428

(57) ABSTRACT

Systems, methods and apparatus are disclosed, including a light collector having a plurality of focusing elements and a plurality of light redirecting features that is optically coupled to one or more photovoltaic (PV) cells. In one aspect, the light collector includes half-cylinder shaped lenses that can focus light incident at various angles onto an elongate v-groove in the light guide such that a first portion of the incident light is diverted to one or more PV cells and a second portion of the incident light is transmitted through the light collector to provide illumination.

### TECHNICAL FIELD

This disclosure relates to the field of light collectors and concentrators, and more particularly to using light guides including focusing optical elements that can track the diurnal and annual movement of the sun to efficiently collect solar radiation at different times during the day and the year.

### DESCRIPTION OF THE RELATED TECHNOLOGY

Solar energy is a renewable source of energy that can be converted into other forms of energy such as heat and electricity. Some drawbacks in using solar energy as a reliable source of renewable energy are low efficiency in collecting solar energy and in converting light energy to heat or electricity, and the variation in the solar energy collection depending on the time of the day and the month of the year.

A photovoltaic (PV) cell can be used to convert solar energy to electrical energy. Systems using PV cells can have conversion efficiencies between 10-20%. PV cells can be made very thin and are not big and bulky as other devices that use solar energy. For example, PV cells can range in width and length from a few millimeters to 10's of centimeters. Although, the electrical output from an individual PV cell may range from a few milliwatts to a few watts, due to their compact size, multiple PV cells may be connected electrically and packaged to produce, in total, a significant amount of electricity. For example, multiple solar panels each including a plurality of PV cells can be used to produce sufficient electricity to satisfy the power needs of some homes.

Solar concentrators can be used to collect and focus solar energy to achieve higher conversion efficiency in PV cells. For example, parabolic mirrors can be used to collect and focus light on PV cells. Other types of lenses and mirrors can also be used to collect and focus light on PV cells. These devices can increase the light collection efficiency. But such systems tend to be bulky and heavy because the lenses and mirrors that are required to efficiently collect and focus sunlight can be large.

Accordingly, for many applications such as, for example, providing electricity to residential and commercial properties, charging automobile batteries and other navigation instruments, it is desirable that the light collectors and/or concentrators are compact in size.

PV materials are also increasingly replacing conventional building materials in parts of the building envelope such as windows, roofs, skylight or facades. PV materials incorporated in building envelopes can function as principal or secondary sources of electrical power and help in achieving zero-energy buildings. One of the currently available building-integrated photovoltaic (BIPV) products is a crystalline Si BIPV, which is made of an array of opaque crystalline Si cells sandwiched between two glass panels. Another available BIPV product is a thin film BIPV which is manufactured by blanket depositing PV film on a substrate and laser scribing of the deposited PV film from certain areas to leave some empty spaces and improve transmission. However, both available BIPV products described above suffer from low transmission (5-20%), disruptive appearance and serious artifacts. Additionally, the thin film BIPV may also be expensive to reasonably manufacture.

Accordingly, BIPV products that can efficiently absorb light and generate energy; improve transmission to illuminate the inside of a building; and track the diurnal/annual movement of the sun to efficiently collect light at various times of the day and different times of the year.

### SUMMARY

The systems, methods and devices of the disclosure each have several innovative aspects, no single one of which is solely responsible for the desirable attributes disclosed herein.

One innovative aspect of the subject matter described in this disclosure can be implemented in a light collecting device that includes a cylindrical-lens array including a top surface for receiving incident light and a bottom surface opposite the top surface, the cylindrical-lens array having half-cylinder-shaped lenses aligned on the top surface to collect incident light, each of the half-cylinder-shaped lenses is characterized by a focal length F, the bottom surface of the cylindrical-lens array being disposed at a distance less than the focal length F such that the half-cylinder-shaped lenses directs light out of the bottom surface, and a light guide having a top surface adjacent the bottom surface of the cylindrical-lens array and a bottom surface opposite the top surface of the light guide, the light guide including a plurality of grooves oriented in the same longitudinal direction as the half-cylinder shaped lenses and disposed along the bottom surface of the light guide, each groove having a depth dimension that extends into the bottom surface of the light guide and each groove defining at least one surface angled to redirect a portion of the focused light from the half-cylinder shaped lenses to one or more edges of the light guide. The light collecting device may be configured such that about 20% to about 80% of light that enters the top surface of the cylindrical-lens array propagates through the light collecting device and out of the bottom surface of the light guide.

In some implementations of the light collecting device, the focal length F is between about 5 mm and about 20 mm. In some implementations, the distance between two consecutive grooves is between about 2 mm and 40 mm. In some implementations a transverse size of each half-cylinder shaped lens is between about 2 mm and about 10 mm. In some implementations, the light collector further includes at least one photovoltaic cell disposed along one or more edges of the light guide. In some implementations, at least two of the half-cylinder-shaped lenses are laterally spaced apart by a first spacing distance. In some implementations, at least two of the half-cylinder-shaped lenses are laterally spaced apart by a second spacing distance, the second spacing distance being different from the first spacing distance. In some implementations, the first spacing distance is between about 0.1 mm and 25 mm and the second spacing distance is between about 0.1 mm and 100 mm. The first spacing distance may be the same for at least two pairs of adjacent half-cylinder shaped lenses in the cylindrical-lens array. In some implementations, the first spacing distance is between about 0.1 mm and 100 mm. In some implementations, the at least two half-cylinder-shaped lenses are characterized by a transversal size, wherein the first spacing distance is less than the transversal size. In some implementations, each of the plurality of grooves is vertically aligned with a center portion of one of the half-cylinder shaped lens. In some implementations, a set of at least two or more grooves are vertically aligned with a center portion of one of the half-cylinder shaped lenses such that light focused by the one half-cylinder shaped lens is incident on the at least two or more grooves and redirected by the at least two or more grooves towards the at least one photovoltaic cell.

In some implementations of the light collection device, the apex of the grooves are vertically offset by approximately 0.1 mm to 5 mm from the focus of the plurality of half-cylinder shaped lenses. In some implementations, the plurality of grooves are spaced apart by a first gap of between about 0.1 mm and 200 mm. In some implementations, a set of the plurality of grooves are offset with respect to an optical axis of corresponding half-cylinder shaped lenses. At least two adjacent grooves may be spaced apart by a first gap and at least two adjacent grooves are spaced apart by a second gap different from the first gap. Each of the plurality of grooves may include two or more turning features. In some implementations, the turning features include at least one of: prismatic features, holographic features, diffractive features, refractive features, reflective features and scattering features. In some implementations, each of the plurality of grooves includes two or more grooves. The light guide may have a refractive index characteristic greater than a refractive index of the cylindrical lens-array. In some implementations, the light collector device further includes a substance having a refractive index lower than a refractive index of the light guide, the substance sandwiched between cylindrical-lens array and the light guide. In some implementations, the light collector device further includes a gap between the light guide and the cylindrical-lens array. In some implementations, an amount of light transmitted through the light collecting device can be selected by selecting a height of the gap. In some implementations the light collector device may be configured as a window of a building.

Another innovative implementations includes a light collecting device, including a plurality of means for focusing incident light configured in an array plate, each of focusing means characterized by a focal length F such that the focusing means half-directs light out of a bottom surface of the array plate, and means for guiding light disposed adjacent to the bottom surface of the array plate, the light guiding means including means for redirecting light oriented in the same longitudinal direction as the focusing means and disposed along a bottom surface of the guiding means. The light collecting device may be configured such that about 20% to about 80% of light that enters plurality of focusing means propagates through the light collecting device and out of the bottom surface of the light guiding means.

In some implementations, the light collecting device further includes at least one photovoltaic cell disposed along one or more edges of the light guiding means. In some implementations, the plurality of focusing means includes a plurality of half-cylinder-shaped lenses. In some implementations, the light guiding means includes a light guide having a top surface adjacent the bottom surface of the cylindrical-lens array and a bottom surface opposite the top surface of the light guide, and wherein the light redirecting means includes a plurality of grooves oriented in the same longitudinal direction as the half-cylinder shaped lenses and disposed along the bottom surface of the light guide, each groove having a depth dimension that extends into the bottom surface of the light guide and each groove defining at least one surface angled to redirect a portion of the focused light from the half-cylinder shaped lenses to one or more edges of the light guide.

Another innovative implementation includes a method of manufacturing a light collecting device, the method including providing a cylindrical-lens array including a top surface for receiving incident light and a bottom surface opposite the top surface, the cylindrical-lens array having half-cylinder-shaped lenses aligned on the top surface to collect incident light, each of the half-cylinder-shaped lenses is characterized by a focal length F, the bottom surface of the cylindrical-lens array being disposed at a distance less than the focal length F such that the half-cylinder-shaped lenses directs light out of the bottom surface, and disposing a light guide having a top surface adjacent the bottom surface of the cylindrical-lens array and a bottom surface opposite the top surface of the light guide, the light guide including a plurality of grooves oriented in the same longitudinal direction as the half-cylinder shaped lenses and disposed along the bottom surface of the light guide, each groove having a depth dimension that extends into the bottom surface of the light guide and each groove defining at least one surface angled to redirect a portion of the focused light from the half-cylinder shaped lenses to one or more edges of the light guide. The plurality of half-cylinder shaped lenses may be disposed laterally spaced apart to define one or more lens spacings LS, the plurality of grooves are disposed laterally spaced apart to define one or more groove spacings GS, and the plurality of grooves are disposed at a distance D from the half-cylinder shaped lenses relative to a focal length of the half-cylinder shaped lenses, and the lens spacings LS, the groove spacings GS and the distance D are selected such that about 20% to about 80% of light that enters the light collecting device is transmitted through the light collecting device and propagates out of the bottom surface of the light guide. In some implementations, the method further includes providing a space between the cylindrical-lens array and the light guide. In some implementations, the method further includes providing a material having a lower refractive index than the refractive index of the light guide in the space. In some implementations, the method further includes disposing at least one photovoltaic cell along one or more edges of the light guide.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

Example implementations disclosed herein are illustrated in the accompanying schematic drawings, which are for illustrative purposes only.

FIG. 1 illustrates an implementation of a light collector including a light guide that is optically coupled to a PV cell.

FIG. 2A is a schematic that illustrates a perspective view of an implementation of a light collector that is configured to efficiently collect light throughout the day.

FIG. 2B illustrates a cross-sectional view of an implementation of a linear v-groove including planar facets S1 and S2 arranged at an angle θ with respect to each other.

FIGS. 2C-2E illustrate cross-sectional views of the implementation illustrated in FIG. 2A and depict the light collection at various times during the day.

FIGS. 3A-3C illustrate perspective views of a portion of the implementation illustrated in FIG. 2A and depict the light collection at various times during the day.

FIGS. 4A and 4B illustrate two different implementations of the light collector illustrated in FIG. 2A, each implementation having a different density (or fill factor) of the half-cylinder shaped lenses and the corresponding plurality of redirecting features.

FIG. 5A depicts an implementation of the light collector located at the equator on the earth's surface.

FIG. 5B illustrates the simulated optical efficiency (i.e., light diverting efficiency) as a function of the incidence angle for implementation illustrated in FIG. 5A.

FIGS. 6A and 6B illustrate different implementations of a light collector including lenses and a plurality of light redirecting features, each implementation configured to collect light that is incident along a first direction that is normal to the light collector and a second direction that is oblique to the light collector.

FIGS. 7A and 7B illustrate the effect of a change in the incidence angle of sunlight due to the earth's rotation on the light diverting efficiency of an implementation of the light collector illustrated in FIG. 1.

FIGS. 8A1-8B2 are simulation results showing the effect of the relative horizontal or vertical movement of different portions of an implementation of the light collector illustrated in FIG. 1.

FIGS. 9A-9C illustrate different implementations of a light collector 800 including a focusing plate 103 and a light guide 101 that can be moved horizontally or vertically with respect to each other to maintain uniform light diverting efficiency through-out the day and/or to transmit a certain amount of incident light through the light collector.

FIG. 10 illustrates an implementation of a light collector that can actively track the movement of the sun across the sky.

FIGS. 11A and 11B are flow charts illustrating two different examples of a method of manufacturing an implementation of a light collecting device.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. As will be apparent from the following description, the innovative aspects may be implemented in any device that is configured to receive radiation from a source and generate power using the radiation. More particularly, it is contemplated that the innovative aspects may be implemented in or associated with a variety of applications such as providing power to residential and commercial structures and properties, providing power to electronic devices such as laptops, personal digital assistants (PDA's), wrist watches, calculators, cell phones, camcorders, still and video cameras, MP3 players, etc. Some of the implementations described herein can be used in BIPV products such as windows, roofs, skylights, doors or facades. Some of the implementations described herein can be used to charge vehicle or watercraft batteries, power navigational instruments, to pump water and for solar thermal generation. The implementations described herein can also find use in aerospace and satellite applications, and other solar power generation applications.

As discussed more fully below, in various implementations described herein, a solar collector and/or concentrator is optically coupled to a PV cell such that light incident on a portion of the collector is provided to the PV cell to generate electrical power. For clarity of description, “solar collector,” “light collector,” or simply “collector” can be used to refer to either or both a solar collector and a solar concentrator, unless otherwise indicated. The light collector can include a plurality of focusing elements that can receive light incident on an exposed surface of the light collector and direct the received light towards a light guide as a focused beam of light. The light guide can include a plurality of redirecting elements that can redirect the focused beam of light towards one or more PV cells that are disposed along one or more edges of the light guide. In various implementations described herein the size, density, and fill factor of the plurality of focusing elements can be selected such that a portion of the light incident on the light collector is transmitted out of the light collector.

In various implementations described herein, the focusing elements can include a plurality of half-cylinder shaped lens, each half-cylinder shaped lens having a curved surface that is disposed about a cylindrical axis. The surface of each half-cylinder shaped lens can have a circular, an elliptical or a parabolic cross-section. Each of the plurality of half-cylinder shaped lenses can be designed and oriented such that light from the sun is incident on at least a portion of the lens curved surface such that the light is focused along a single line by each lens at any one time as the sun's position relative to earth moves changes from east to west during the day. In such implementations, the light redirecting elements can include elongate grooves that are oriented in the same direction as the cylindrical axis and positioned at a distance equal to the focal length of the plurality of half-cylinder shaped lenses. In such implementations, light from the sun can be focused by each of the half-cylinder shaped lens is incident on a corresponding elongate groove throughout the day.

In various implementations, the light collector can include one or more actuators that can change the relative horizontal and/or vertical positions between the plurality of focusing elements and the plurality of light redirecting elements. Changing these relative positions can change the position of the plurality of light redirecting elements relative to the focal point which can change the focal point to increase the amount of photovoltaic power generated and/or change the amount of light transmitted through the light collector. Additionally, the one or more actuators can be useful to adjust the relative positions of the focusing elements and the light redirecting features corresponding to the movement of the sun through the day or the year, thereby increasing the efficiency of light collection.

Particular implementations of the subject matter described in this disclosure can be implemented to realize one or more of the following potential advantages. A light collector, such as, for example, the implementations described herein can be used to collect, concentrate, and direct sunlight or ambient light to PV cells in devices that convert light energy into electricity with increased efficiency and lower cost. Additionally, the implementations described herein can be configured to transmit a portion of the incident sunlight or ambient light through the light collector. Accordingly, the various implementations of the light collector described herein can be used to generate PV power while simultaneously providing illumination from received incident light. Thus, the implementations described herein can be integrated in architectural structures such as, for example, windows, roof, skylights, or facades to simultaneously generate photovoltaic power and transmit sunlight or ambient light to the interior of the architectural structures. Some implementations of the light collector, described herein can efficiently collect light at various times during the day or the year. For example, the implementations of the light collector described herein can efficiently collect light incident at noon when sun is overhead and sunlight is incident at angles closer to a surface normal of the light collector as well as in the mornings and evening when light is incident at non-normal angles.

FIG. 1 illustrates an implementation of a light collector 100 including a light guide 101 that is optically coupled to a PV cell 105. The light guide 101 includes a forward surface 112 and a rearward surface 113, opposite the forward surface 112. A person having ordinary skill in the art will appreciate that the terms “forward” and “rearward” as used in referring to light collector surfaces herein do not indicate a particular absolute orientation, but instead are used to indicate a light collecting surface (“forward surface”) on which natural light is incident and a surface where a portion of the incident light received on the forward surface can propagate out from (“rearward surface”). In this implementation, light incident on the forward surface 112 has first passed through a focusing plate 103. A plurality of edges 116 are enclosed between the forward and rearward surfaces 112 and 113 of the light guide 101. As illustrated in FIG. 1, a PV cell 105 is disposed with respect to one of the edges 116 of the light guide 101. Although only one PV cell 105 is illustrated in FIG. 1, it is understood that one or more additional PV cells can be disposed along one or more of the other edges 116 of the light guide 101. In various implementations, the light guide 101 may be optically coupled to the PV cell 105 by using optical coupling elements such as lenses, fibers, prisms, etc. The focusing plate 103 includes an array of focusing elements 114 is disposed on, or over, the forward surface 112 of the light guide 101. The array of focusing elements 114 are configured to focus the received ambient light 102 onto the light guide 101 as a focused beam of light represented by ray 115. The light guide 101 illustrated in FIG. 1 includes a plurality of light redirecting features 110 that are configured to divert or turn a first portion of light that is incident on the forward surface of the light guide 101 towards the PV cell 105. The array of focusing elements 114 and the plurality of light redirecting features 110 can be configured such that a second portion of light that is incident on the forward surface is transmitted out of the light guide 101 through the rearward surface 113. In FIG. 1, ray 120 is representative of a second portion of the received light that propagates out of the light guide 101 from the rearward surface 113. In FIG. 1, ray 125 is a representative of a diverted portion of light which propagates through the light guide 101 by successive total internal reflections of the forward and the rearward surfaces towards the PV cell 105. In various implementations, the light guide 101 can include a transparent or transmissive material such as glass, plastic, polycarbonate, polyester or cyclo-olefin. The forward and rearward surfaces 112 and 113 of the light guide 101 can be parallel or nearly so. In other implementations, the light guide 101 can be wedge shaped such that the forward and rearward surfaces are inclined with respect to each other. The light guide 101 may be formed as a plate, sheet or film, and fabricated from a rigid or a semi-rigid material. In various implementations, portions of the light guide 101 may be formed from a flexible material.

In various implementations, the plurality of light redirecting features 110 may be disposed on the forward or rearward surfaces 112 and 113 of the light guide 101. The plurality of light redirecting features 110 can include elongated grooves, v-grooves, scattering features, optical refractive, reflective or diffractive features. In some implementations, the light guide 101 can include a substrate and a film or a plate provided with the plurality of light redirecting features 110 can be adhered or attached to the substrate. In various implementations, the plurality of light redirecting features 110 can be manufactured using methods such as etching, embossing, imprinting, lithography, etc. In some implementations, the plurality of light redirecting features 110 can include white paint that is applied to the forward or rearward surfaces 112 and 113 of the light guide 101.

In various implementations, the array of focusing elements 114 can include a plurality of lenses, a lenslet array, and an array of microlenses. The array of focusing elements 114 can have hemispherical, hemi-cylindrical, parabolic or elliptical surfaces. Each of the plurality of focusing elements in the array 114 can be characterized by a focal length F. The light guide 101 can be disposed relative to the focusing plates 103 such that incident light is focused onto the plurality of light redirecting features 110 by the array of focusing elements 114. In some implementations, the array of focusing elements 114 can be disposed on a rearward surface of the focusing plate 103. The focusing plate 103 can be rigid or flexible. In various implementations, the focusing plates 103 can be separated from the forward surface of the light guide 101 by a gap. In some implementations, the gap can include a layer of material having a lower refractive index than the refractive index of the material of the light guide. For example, the gap can include air or nitrogen. In other implementations, the gap can include a material that matches the refractive index of the array of focusing elements 114 to the refractive index of the light guide 101. In some implementations, the array of focusing elements 114 can be disposed on the forward surface of the light guide 101 and the plurality of light redirecting features 110 can be disposed on the rearward surface of the light guide 101.

An implementation similar to the light collector 100 illustrated in FIG. 1 can be used as a (building-integrated photovoltaic) BIPV product (for example, window, skylight, facade, door, glazing, or a curtain wall). A BIPV product using a light collector 100 or other implementations of a light collector as described herein can reduce the cost of the BIPV product since the PV cells are used only at the edges of the light guide (for example, light guide 101). High efficiency Si or III-V solar cells can be used in various implementations to increase the photoelectric conversion efficiency. A BIPV product using a light collector 100 or other implementations of a light collector as described herein can additionally reduce color dispersion and image distortion; serve as thermal barrier and block solar radiation thereby aid in reducing heating and cooling costs; be designed to meet advanced building codes and standards; minimize fire hazard; supply better daylight as compared to conventional BIPV products; recycle indoor lighting energy; help in achieving “net zero building” by generating electric power, be cut into arbitrary shapes and sizes according to the building requirement; be compatible with curved glass windows and be aesthetically pleasing as conventional windows. Additionally, a BIPV product using a light collector 100 or other implementations of a light collector as described herein can be used for windows, privacy screens, skylights, etc. since the amount of light transmitted through the collector can be varied or controlled by varying or controlling a density or fill factor of the plurality of optical features during manufacturing. A BIPV product using a light collector 100 or other implementations of a light collector as described herein can be used to compensate for diurnal movement of the sun with or without mechanically displacing portions of the light collector to increase the efficiency of light collection.

FIG. 2A illustrates a perspective view of an implementation of a light collector 200 that is configured to efficiently collect light at all times of the day. The light collector 200 can divert a first portion of the collected light towards one or more PV cells 210 and transmit a second portion of the collected light out of the light collector 200. The illustrated light collector 200 can simultaneously generate PV power and provide illumination to the interior of the structure it is disposed on. Accordingly, the illustrated light collector 200 can be used as a power generating window or skylight. The light collector 200 is a two-piece light collecting structure that includes a focusing plate 201 having a cylindrical lens array including a plurality of half-cylinder shaped lenses (or focusing lenses) 204a, 204b and 204c and a light guide 205 that includes a plurality of light redirecting features 207 (e.g., 207a, 207b and 207c, also referred to as “redirecting features 207” for ease of reference). The light collector 200 can also include other structures which provide structural support or change an optical characteristic. Where appropriate, structures and features of light guide 101 discussed above may be incorporated into light guide 205. For example, light guide 205 may be made of the same or similar materials as those discussed for light guide 101. As another example, the plurality of redirecting features 207 can be fabricated using methods similar to the fabrication of the plurality of light redirecting features 110.

The PV cell 210 can convert light into electrical power. In various implementations, the PV cell 210 can include solar cells. The PV cell 210 can include a single or a multiple layer p-n junction and may be formed of silicon, amorphous silicon or other semiconductor materials such as Cadmium telluride. In some implementations, PV cell 210 can include photo-electrochemical cells. Polymer or nanotechnology may be used to fabricate the PV cell 210. In various implementations, PV cell 210 can include multispectrum layers, each multispectrum layer having a thickness between approximately 1 μm to approximately 250 μm. The multispectrum layers can further include nanocrystals dispersed in polymers. Several multispectrum layers can be stacked to increase efficiency of the PV cell 210.

The focusing plate 201 and/or the light guide 205 may be formed as a plate, sheet or film. In various implementations, the focusing plate 201 and/or the light guide 205 may be fabricated from a rigid or a semi-rigid material or a flexible material. In various implementations, the focusing plate 201 and/or the light guide 205 can have a thickness of approximately 1-10 mm. In some implementations, the overall thickness of the light collector 200 can be less than approximately 4-8 inches.

The focusing plate 201 includes a substrate having a forward surface that receives incident light and a rearward surface through which light propagates out of the focusing plate 201. In the implementation illustrated in FIG. 2A, the plurality of lenses 204a-204c are disposed on the forward surface of the focusing plate 201. However, in other implementations, the plurality of lenses 204a-204c can be disposed on the rearward surface of the focusing plate 201. In some implementations, the plurality of lenses 204a-204c can be formed on the forward or rearward surface of the focusing plate 201. In some implementations, a film, a layer or a plate provided with the plurality of lenses 204a-204c can be adhered, attached or laminated to the forward or rearward surface of the focusing plate 201. In various other implementations, the plurality of lenses 204a-204c can be disposed through-out the volume of the focusing plate 201. The plurality of lenses 204a-204c can be formed by a variety of methods and processes, including lithography, etching, and embossing.

Each lens 204a, 204b and 204c has a curved surface S disposed about a cylinder axis 202. The curved surface S has a transversal size D. The transversal size D can be between 0.1 mm and 15 mm. The curved surface S can have a circular, elliptical or a parabolic cross-section. In various implementations, the curved surface S can have an aspheric cross-section. Each lens 204a, 204b and 204c includes an optical axis 203 and is characterized by a focal length F that depends on the curvature and the transversal size D of the curved surface S. The focal length F can be between 3 mm and 80 mm. In some implementations, the lenses 204a-204c can have the same transversal size D and/or focal length F. However, in other implementations, the transversal size D and/or the focal length F for each of the lenses 204a-204c can be different. The distance between the plurality of lenses 204a-204c and the bottom surface of the focusing plate 201 can be less than the focal length F such that ambient light focused by the plurality of lenses 204a-204c is directed out of the focusing plate 201.

In FIG. 2A, the lenses 204a, 204b and 204c are spaced apart from each other by a gap. For example, in FIG. 2A the optical axes of lenses 204a and 204b are spaced apart by a first spacing distance L1 and the optical axes of lenses 204b and 204c are spaced apart by a second spacing distance L2. In various implementations, the lenses 204a, 204b and 204c can be regularly spaced apart from adjacent lenses such that consecutive lenses are spaced apart by a uniform distance. For example, the first spacing distance L1 is approximately equal to the second spacing distance between the optical axes of lenses 204b and 204c. In some implementations, the lenses 204a, 204b and 204c can be irregularly spaced apart from adjacent lenses such that consecutive lenses are spaced apart by a non-uniform distance. For example, the first spacing distance L1 between is greater than or less than the second spacing distance L2. Implementations including irregularly spaced apart lenses 204a-204c can be advantageous to reduce Moiré fringes. In other implementations having more than three lenses, the first spacing distance L1 can be the same for at least two pairs of adjacent lenses. In various implementations, the first spacing distance and the second spacing distance can be between 0.1 mm and 25 mm. In some implementations, the first spacing distance L1 and/or the second spacing distance L2 can be greater than or less than the transversal size D. In various implementations, adjacent lenses 204a, 204b and 204c can abut each other such that the distance between the optical axes of adjacent lenses 204a, 204b and 204c is equal to the transversal size D. The spacing between adjacent lenses 204a, 204b and 204c can be selected during manufacturing to vary the light collection efficiency and the transmissivity of the focusing plate 201. For example, when the spacing between adjacent lenses 204a, 204b and 204c is reduced, the light collection efficiency is increased while the transmissivity of the focusing plate is decreased. Conversely, when the spacing between adjacent lenses 204a, 204b and 204c is increased, the light collection efficiency is decreased while the transmissivity of the focusing plate is increased.

The light guide 205 has a forward surface which receives incident light and a rearward surface opposite the forward surface through which light is transmitted out of the light guide 205. The forward surface of the light guide 205 is closer to the focusing plate 201. In various implementations, the forward surface of the light guide 205 can be adjacent or in contact with the rearward surface of the focusing plate 201. In the illustrated implementations, the plurality of redirecting features 207 are disposed on or over the rearward surface of the light guide 205, and protrude into the light guide 205 from the back surface. However, in other implementations, the plurality of redirecting features 207 can be disposed on or over the forward surface of the light guide 205. In other implementations, the plurality of redirecting features 207 can extend into the bottom surface of the light guide 205. The plurality of light redirecting features 207 can be manufactured using methods such as lithography, etching, imprinting, embossing, etc. In some implementations, the plurality of light redirecting features 207 can be provided on a film, a layer or a plate that is adhered, laminated or attached to the forward or rearward surface of the light guide 205.

In the illustrated implementation, the plurality of redirecting features 207 are linear v-grooves that extend into the light guide 205. However, in other implementations, the plurality of redirecting features 207 can be optical refracting, reflecting, diffracting or scattering features. In various implementations, the plurality of redirecting features 207 can include v-grooves having non-linear extent. For example, the axis of the v-grooves may be curved (e.g., circular or elliptical). V-grooves having non-linear extent may be advantageous to collect diffused ambient light, for example, under cloudy conditions. V-grooves arranged along curved paths may be also advantageous in focusing the ambient light. In various implementations, the side walls of V-grooves can be a generic quadratic curve, or a portion of a quadratic curve. For example, the side walls can be i.e, elliptical, parabolic, hypobolic or other higher order aspheric curves. V-grooves with curved sidewalls can have optical power to focus and/or concentrate the ambient light. The non-linear turning surface has surface normal that is tilted with respect to a normal to the light guide to efficiently collect off-axis light. FIG. 2B illustrates a cross-sectional view of a linear v-groove 207a including planar facets S1 and S2 arranged at an angle θ with respect to each other. The angle between the planar facets can be between approximately 20 degrees and approximately 150 degrees. In various implementations, each linear v-groove can include two or more turning features. The turning features can include prismatic features, diffractive features, refractive features, reflective features, scattering features, holographic features, etc. Each linear v-groove 207 can correspond to one of the focusing lenses 204a, 204b and 204c. In various implementations, each linear v-groove 207 can be registered with a corresponding lens 204a, 204b, and 204c such that the apex of each linear v-groove coincides or is vertically aligned (relative to the illustrated orientation in FIG. 2A) with the optical axis 203 of the corresponding lens 204a, 204b and 204c. In various implementations, the apex of each linear v-groove 207a, 207b, and 207c can be offset from the optical axis 203 of the corresponding lens 204a, 204b and 204c. In some implementations, the offset distance can depend on the latitude of the geographical location where the light collector 200 is disposed. In various implementations, the offset distance can be between approximately 0.01 mm and 0.5 mm. In some implementations, two or more v-grooves can be vertically aligned with the optical axis 203 of one lens such that light focused by one half-cylinder shaped lens is incident on the two or more v-grooves and subsequently directed towards the PV cell 210 by the two or more v-grooves. The plurality of linear v-grooves 207a-207c are oriented in the same longitudinal direction as the lenses 204a-204c. The plurality of linear v-grooves 207a-207c can have a depth dimension d that extends into the bottom surface of the light guide 205. In various implementations, the depth dimension d of each linear v-groove can have a value between approximately 0.001 mm to approximately 3 mm. In various implementations, the apex of the grooves can be vertically offset by approximately 0.1 mm to 5 mm from the focus of the plurality of cylindrical lenses.

In FIG. 2A, the plurality of redirecting features 207a, 207b and 207c are spaced apart from each other such that a region that is devoid of redirecting features is included between the plurality of redirecting features 207a-207c. For example, in FIG. 2A the redirecting features 207a and 207b are spaced apart by a first gap distance g1 and the redirecting features 207b and 207c are spaced apart by a second gap distance g2. In various implementations, the plurality of redirecting features 207a, 207b and 207c can be regularly spaced apart from adjacent redirecting features such that consecutive redirecting features are spaced apart by a uniform distance. For example, the first gap distance g1 can be approximately equal to the second gap distance g2. In some implementations, the redirecting features 207a, 207b and 207c can be irregularly spaced apart from adjacent redirecting features such that consecutive redirecting features are spaced apart by a non-uniform distance. In other words, the first gap distance g1 can be greater than or less than the second gap distance g2. In various implementations, the first gap distance g1 and the second gap distance g2 can vary between approximately 0.1 mm and 25 mm. In various implementations, adjacent redirecting features 207a, 207b and 207c can be disposed to abut each other such that there is no gap between adjacent redirecting features 207a, 207b and 207c. The spacing between the plurality of redirecting features 207a, 207b and 207c can be selected to vary the light collection efficiency and the transmissivity of the light guide 205. For example, when the spacing between adjacent redirecting features 207a, 207b and 207c is reduced, the transmissivity of the light guide 205 is decreased. Conversely, when the spacing between adjacent redirecting features 207a, 207b and 207c is increased, the transmissivity of the light guide 205 is increased. The spacing between adjacent redirecting features 207a, 207b and 207c can also affect the light guiding efficiency. For example, if the spacing between adjacent redirecting features 207a, 207b and 207c is decreased, light propagating through the light guide 205 can suffer scattering losses due to repeated interaction with the plurality of redirecting features, thereby, decreasing the light guiding efficiency.

Still referring to FIG. 2A, one or more PV cells 210 are arranged along one or more edges of the light collector 200. In various implementations, there may be a gap 212 between the focusing plate 201 and the light guide 205. In various implementations, the gap 212 may include a layer of material (e.g., air, nitrogen, argon, or a viscous material) having a refractive index lower than the refractive index of the material of the light guide 205. In other implementations, the gap 212 can be wholly or partially devoid of material or substance, and can be a vacuum. The height of the gap 212 can vary between approximately 1 mm- and 50 (mm. In some implementations, the material of focusing plate 201 can have a lower refractive index than the material of the light guide 205 such that the gap 212 can be eliminated. In various other implementations, the gap 212 can include a layer of material having a refractive index that matches the refractive index of the focusing plate 201 to the refractive index of the light guide 205.

The light collector 200 can be configured to efficiently collect sunlight at different times during the day, as further discussed below. FIGS. 2C-2E illustrate cross-sectional views of the implementation illustrated in FIG. 2A and depict the light collection at various times during the day. FIGS. 3A-3C illustrate perspective views of a portion of the implementation illustrated in FIG. 2A and depict the light collection at various times during the day. To efficiently collect sunlight at all times during the day the half-cylinder shaped lenses 204a, 204b and 204c can be positioned such that the array of lenses is arranged in a north-south orientation; that is, so the cylindrical axis of each lens is oriented generally along the east-west direction such that at noon on an equinox the rays of the sun are incident on the each of the lenses 204a, 204b and 204c along the optical axis 203 of each of the lenses 204a, 204b and 204c. On other days, the rays of the sun at noon time are incident on the lenses 204a, 204b and 204c from a direction that is at an angle (plus or minus) with respect to the optical axis 203 of each of the lenses 204a, 204b and 204c. The angle between the incident direction of sunlight at noon time and the optical axis 203 of each of the lenses 204a, 204b and 204c can depend on the latitude of the geographical location where the light collector is disposed and the time of the year. The lenses 204a, 204b, and 204c are designed and configured to focus the light on to a corresponding linear v-groove 207a, 207b, and 207c (which may collectively be referred to as linear v-grooves or grooves 207) at all times of the day as shown in FIGS. 2C-2E and 3A-3C thus providing a focused beam of light in a position that corresponds with the diurnal relative movement of the sun. When implemented in a window device, the cylindrical axis of the half-cylinder shaped lenses is generally aligned along the same direction as the track of the sun's diurnal movement. This can advantageously allow the window device to collect light efficiently at various times during the day and year.

FIG. 2C and FIG. 3B illustrate an example of light collection by the light collector 200 at noon. At noon when the sun is highest overhead, the collector 200 can be positioned such that the sun's rays 215 are incident on the focusing plate 201 along a direction approximately parallel to the optical axis 203 of the lenses 204a, 204b and 204c. The lenses 204a, 204b and 204c focus the incident light 215 along a line which coincides with the corresponding linear v-groove 207a as shown in FIG. 3B. The linear v-groove 207a redirects the focused light such that redirected light 225 (FIG. 2C) propagates through the light guide 205 towards the PV cell 210. FIG. 2D and FIG. 3A illustrate the light collection by the light collector 200 in the morning when the rays of the sun 218 are incident on the light collector 201 from the east and FIG. 2E and FIG. 3C illustrate the light collection by the light collection by the light collector 200 in the evening when the rays of the sun 221 are incident on the light collector 201 from the west.

With reference to FIGS. 2C-2E and 3A-3C, ambient light 215, 218 and 221 incident on the focusing plate 201 are focused by the lenses 204a, 204b and 204c such that focused beams of light 220 (FIG. 2C), 223 (FIG. 2D) and 226 (FIG. 2E) are directed onto a corresponding linear v-groove 207a, 207b and 207c. The linear v-grooves 207 are adapted to redirect the focused light so that the redirected beams of light 225 (FIG. 2C), 228 (FIG. 2D) and 231 (FIG. 2E) propagate towards the PV cells 210 disposed along the edges of the light guide 205.

Ambient light that enters the light collector 200, but is not redirected by the plurality of light redirecting features (or linear groves) 207 may propagate through the light collector 200. In various implementations, the density or fill factor of the half-cylinder shaped lenses 204a, 204b, and 204c is configured such that the amount of light transmitted through the light collector 200 may vary (for example, from 0% to 100% transmission). In some implementations, the light collector is configured such that the amount of transmitted light is between about 25% and 75%, for example, about a 40% or about a 50% transmission measured at a certain sun angle (for example, such that it is at a normal angle to the light collector orientation. In some implementations, there is one linear groove 207 corresponding to each lense 204. In some implementations there are two or more linear grooves 207 corresponding to each lense. This may be done to take into account the “movement” of the focused beam (for example, focused beam 223 in FIG. 2D) as a result of changes in the relative position of the sun and the light collector 200. By configuring some portions of the light receiving surface of the focusing plate 201 to have fewer cylindrical lenses 204 (for example, such that there is a portion of the light receiving surface on the light collector 200 that is not part of a lens) and one of the linear grooves 207 is associated with each lens 204, a greater amount of the incident light falling on the light collector 200 will be transmitted through the light collector 200 when compared to a configuration having no space between the lenses. In other words, light that is not subject to being focused by a lens 204 and redirected by a linear grove 207 can pass through the light collector 200. In some implementations, the focusing lenses 204 allow for a transmission if 50% of the light when the light source is at a normal incident angle with respect to the light collector 200.

In various implementations, the density or fill factor of the plurality of lenses 204a, 204b, and 204c and the plurality of light redirecting features 207a, 207b, and 207c can be selected to transmit a certain percentage of the ambient light incident on the light collector 200, for example, in the range of approximately 20%-80% of the ambient light incident on the light collector 200. In some non-limiting example implementations, the focusing lenses 204 and the light redirecting linear grooves 207 can be configured to transmit a certain amount of light (in relation to the amount of light that enters the light collector 200), for example, approximately 20-30%, 30-40%, 40-50%, 50-60%, 60-70%, or 70-80% of the ambient light incident on the light collector 200 by changing one or more characteristics of either or both of the focusing lenses 204 and the linear grooves 207. For example, the size of the focusing lenses 204 (for example, diameter), the size of the linear grooves 207 (e.g., facet height, area of the facet surface exposed to the focused light beam), density of the focusing lenses 204, and/or the size of a focused beam of light.

FIGS. 4A and 4B illustrate two different implementations of the light collector 200 illustrated in FIG. 2A, each implementation having varying density or fill factor of the half-cylinder shaped lenses and the plurality of redirecting features. The implementation illustrated in FIG. 4A has a higher density of fill factor of the lenses 204a-204c and the plurality of redirecting features 207a-207c as compared to the implementation illustrated in FIG. 4B. Accordingly, the implementation illustrated in FIG. 4B will transmit more received ambient light than the implementation shown in FIG. 4A. In various implementations, some of the plurality of redirecting features 207a-207c corresponding with one or more lenses 204a-204c may be omitted to vary the amount transmitted through the light collector 200. In various implementations, the height of the gap 212 between the focusing plate 201 and the light guide 205 can be varied to change the amount of light transmitted through the light collector 200.

In various implementations, thin films having reflecting, diffracting or scattering features can be disposed forward or rearward of the focusing plate 201 and/or the light guide 205. The thin films can be used to increase the light collection efficiency, provide visual effects, increase or decrease transmission or to provide other optical function.

The various implementations, described in FIGS. 2A-4B can thus be used as power generating windows which can collect light efficiently at various times during the day. In various implementations, the power generating window including the light collecting structure can have varying degrees of transmissivity.

In various implementations, a PV power generating window including the implementations of the light collector 200 illustrated in FIGS. 2A-4B can be obtained by assembling the focusing plate 201, the light guide 205 and the PV cells 210 in a frame including electrical connections. In various implementations, the electrical connection may be embedded in the light guide 204. Implementations of a PV power generating window including the implementations of the light collector 200 illustrated in FIGS. 2A-4B can provide an aesthetically pleasing appearance, can efficiently collect and divert light to the PV cell at various times during the day and have a varying degree of transmissivity. In various implementations, implementations of a PV power generating window including the implementations of the light collector 200 illustrated in FIGS. 2A-4B can have a visual effect comparable to or better than a window screen.

The light diverting efficiency of light collectors (in other words, the amount of light diverted towards the PV cell 210 by the light collector 200 illustrated in FIG. 2A) can depend on the angle of incidence θ of the ambient light, the solar elevation and azimuth angles due to the sun's apparent movements through the sky from morning to evening due to earth's rotation and shifts from north to south in the northern hemisphere due to the earths revolution. For example, in some implementations, ambient light that is incident in a certain fixed range of angles can be efficiently collected and diverted towards the PV cell 210 by the light collector 200 and the light diversion efficiency decreases when light is incident at other angles outside the fixed range. The variation of the light collection efficiency on the incident angle is depicted in FIG. 5B which illustrates the simulated optical efficiency (i.e., light diverting efficiency) as a function of the incidence angle.

For the purpose of simulation, an implementation of the light collector 200 is considered to be located at the equator as shown in FIG. 5A. The equatorial plane is represented by the x-y plane. The simulated implementation includes cylindrical lens array including a plurality of half-cylinder shaped lenses having a radius of curvature of approximately 10 mm, focal length of approximately 19 mm. The adjacent lenses of the cylindrical lens array are spaced apart by a distance of approximately 7.9 mm. For simulation purposes, the v-grooves are assumed to have an apex angle of about 90 degrees, a height of about 2 mm. The consecutive v-grooves are spaced apart by a distance of about 7.9 mm. The v-grooves are disposed such that the plurality of light redirecting features is aligned along the y-axis, which represents the east-west direction. With reference to the implementation illustrated in FIG. 5A, the track of the sun moves along a path from A→C→E in the x-z plane from winter to summer. During the day, the sun moves along a path from B→C→D in y-z plane.

FIG. 5B illustrates the simulated optical efficiency (i.e., light diverting efficiency) as a function of the incidence angle for implementation illustrated in FIG. 5A. The light diverting efficiency versus the angle of incidence of the ambient sunlight with respect to z-axis as the sun moves across the sky along a path from B→C→D during the day is shown by curve 315 in FIG. 5B. Curve 315 represents the light diverting efficiency calculated at 12:00 pm every day for the entire year. The light diverting efficiency versus the angle of incidence of the ambient sunlight with respect to z-axis as the sun moves across the sky along a path from A→C→E during the year is shown by curve 320 in FIG. 5B. Curve 320 is the light diverting efficiency for a specific day of the year when sun is at point C for the entire day. Curves 315 and 320 represent the decomposed performance from two distinct incident direction. In general, the solar performance will be a combination of the performance 315 and 320 depending on the location of the sun.

It is observed from curve 315 that the light collection efficiency decreases gradually from a peak value of about 76% as θ varies from 0 degrees to about 23 degrees beyond which it decreases sharply. If the light collector were located at a different place on earth located above or below the equator, the peak will shift to an angle of incidence that is equal to the latitude of the place ±23 degrees. It is observed from curve 320 that the light collection efficiency has a peak value of about 76% at θ of about 0 degrees and a second peak value of about 25% at θ of about 23 degrees. If the light collector were located at a different place on earth located above or below the equator, the first peak will occur at an incident angle that is equal to the latitude of the place and the second peak will occur at an incident angle that is equal to the latitude of the place ±23 degrees.

The size of the plurality of light redirecting features 110 and the spacing between consecutive light redirecting features can affect the light guiding efficiency of the light collector 100. For example, if the size of the plurality of redirecting features 110 and/or or the density of the plurality of redirecting features 110 is large, then light propagating within the light guide 101 can strike the plurality of redirecting features 110 and be scattered out of the light guide 101. The light collecting efficiency of the collector 100 can be reduced in this manner. In order to reduce scattering loss during propagation through the light guide 101, the plurality of light redirecting features 110 can have a density between 0.1% and 10% of the area of the light guide, such that the light guide 101 includes regions that are devoid of the light redirecting features 110. Additionally, in various implementations, the transverse size of the plurality of light redirecting features 110 can be between 0.1 mm and 5.0 mm and the height of the plurality of light redirecting features 110 can be between 0.1 mm and 1.0 mm such that light is efficiently collected without being scattered out of the light guide 205. However, reducing the size of the plurality of light redirecting features 110 can reduce the area over which incident light focused by the array of focusing elements 114 is turned and efficiently guided by the light guide 101. For example, light that is incident on the light collector 100 at different angles is focused by each focusing element in the array of focusing elements 114 to different spatial positions in the plane of the light guide 101. Depending on the size, density and the position of the plurality of light redirecting features 110, light incident in a certain angular range is focused on the plurality of light redirecting features 110 while light incident at other angles strikes a region of the light guide 101 that is devoid of light redirecting features 110. Focused light that is not incident on a light redirecting feature is not turned and collected by the light guide 101 but instead exits out of the light guide 101. Accordingly, the range of incidence angles over which the light collector 100 can efficiently collect light can depend on a variety of factors including but not limited to size of the plurality of light redirecting features 110, density of the plurality of light redirecting features 110 and the with respect to the array of focusing elements 114. For example, consider implementations, wherein each of the plurality of light redirecting feature is arranged below (or rearward of) a corresponding focusing element from the array of focusing elements 114, such that the light redirecting feature is not offset with respect to the optical axis of the corresponding focusing element. In such implementations, light that is incident in an angular range of about 5-20 degrees with respect to a normal to the focusing plate 103 (or the optical axis of the focusing elements) can be efficiently collected and guided by the light guide 101, while light incident at angles outside this angular range exits the light guide 101 and is not collected. This can affect the light collection efficiency of the light collector 100 as the incident sunlight changes direction from east to west through the day and as the direction of incident sunlight changes seasonally during the year. Implementations of light collectors described herein, including implementations 600 and 650 discussed below can increase the angular range over which incident sunlight is efficiently collected.

FIGS. 6A and 6B illustrate different implementations of a light collector including lenses and a plurality of light redirecting features, each implementation configured to collect light that is incident along a first direction that is normal to the light collector and a second direction that is oblique to the light collector. The implementation of the light collector 600 illustrated in FIG. 6A includes a plurality of light guides 101a, 101b and 101c disposed below (or rearward of) the focusing plate 103. In various implementations, the plurality of light guides 101a-101c can include the same transmissive material. In other implementations, the plurality of light guides 101a-101c can include different transmissive materials. As discussed above, the focusing plate 103 includes an array of focusing elements 114. Each focusing element 114a in the array has an optical axis 603. In various implementations, the optical axis 603 can be parallel to a normal to the surface of the focusing plate 103 on which the array of focusing elements 114 is disposed. In various implementations, the plurality of light guides 101a-101c can be disposed with respect to the focusing plate 103 such that a gap 601 is included between the focusing plate 103 and the plurality of light guides 101a-101c. In various implementations, the gap 601 can include a material having a refractive index that is lower than the material of the light guide 101a and the focusing plate 103. One or more PV cells 105 can be disposed with respect to one or more edges of the plurality of light guides 101a-101c.

Each of the plurality of light guides 101a, 101b and 101c includes a plurality of light redirecting features. For example, light guide 101a includes light redirecting features 110a and 110b; light guide 101b includes light redirecting features 110′a and 110′b; and light guide 101c includes light redirecting features 110″a and 110″b. The plurality of light redirecting features 110a and 110b in the first light guide 101a are disposed rearward of the plurality of focusing elements 114a and 114b in the array 114 such that each redirecting feature is aligned with the optical axis 603 of a corresponding focusing element. For example, the redirecting feature 110a is aligned with the optical axis of the focusing element 114a and the redirecting feature 110b is aligned with the optical axis of the focusing element 114b. The plurality of light redirecting features 110′a and 110′b in the second light guide 101b and the plurality of light redirecting features 110″a and 110″b in the third light guide 101c are disposed rearward of the plurality of focusing elements 114a and 114b in the array 114 such that redirecting features 110′a, 110′b, 110″a and 110″b are offset from the optical axis 603 of the corresponding focusing element 114a and 114b. In various implementations, the offset distance can be between 0.01 mm and about one-half the spacing between an adjacent focusing element. In some implementations, the offset distance can be between 0.01 mm and 0.5 mm.

In some implementations, a gap can be included between the light guide 101a and the light guide 101b and/or the light guide 101b and light guide 101c. In various implementations, the gap can include a material having an index of refraction lower than the refractive index of the material of the light guides 101a, 101b and 101c. The vertical distance between each of the plurality of light guides 101a-101c and the focusing plate 103, L1, L2 and L3, can be selected such that plurality of light redirecting features 110a, 110b, 110′a, 110′b, 110″a and 110″b are within a distance Δf of the focal length f of each focusing element in the array 114. In various implementations, Δf can be between about 1%-10% the focal length f. In various implementations, the vertical distance between the light guide 101a and the focusing plate 103, L1 can be between 1 mm and 10 mm. In various implementations, the vertical distance between the light guide 101b and the focusing plate 103, L2 can be between 1 mm and 20 mm. In various implementations, the vertical distance between the light guide 101c and the focusing plate 103, L3 can be between 1.0 mm and 30.0 mm.

Light that is incident on the plurality of focusing elements 114a and 114b at incident angles between approximately 0 degrees and approximately 60 degrees with respect to the optical axis 603 is focused by the focusing elements 114a and 114b toward the light redirecting features 110a and 110b that are aligned with the optical axis 603. Light incident on the plurality of light redirecting features 110a and 110b is turned inward and guided within the light guide 101a toward the PV cells 105. For example, in the illustrated implementation, ray of light 615 that is incident along a direction parallel to the optical axis 603 is focused toward the toward the light redirecting features 110a and 110b such that it is turned by the light redirecting features 110a and 110b and guided by total internal reflection in the first light guide 101a.

Light that is incident on the plurality of focusing elements 114a and 114b at oblique angles with respect to the optical axis 603 is focused by the focusing elements 114a and 114b toward the light redirecting features 110′a, 110′b, 110″a and 110″b that are offset from the optical axis 603. In various implementations, light incident in the angular range between about 20 degrees and about 70 degrees with respect to the optical axis 603 can be focused toward the light redirecting features 110′a, 110′b, 110″a and 110″b such that it is guided in the second light guide 101b or the third light guide 101c. For example, ray 610 which is incident at an oblique angle between about 20 degrees and about 70 degrees with respect to the optical axis 603 is incident on the light redirecting feature 110′a and turned by the redirecting feature 110′a such that it is guided in the second light guide 101b by multiple total internal reflections toward the PV cell 105. As another example, ray 612 which is incident at an oblique angle between about 20 degrees and about 70 degrees with respect to the optical axis 603 is incident on the light redirecting feature 110″b and turned by the redirecting feature 110″b such that it is guided in the third light guide 101c by multiple total internal reflections toward the PV cell 105. In this manner the implementation 600 can be used to collect solar light that is incident in a wide range of angles (for example, between about 0 degrees and about 70 degrees with respect to the optical axis 603).

The angular range over which incident light is collected can depend on various factors including but not limited to the focal length of the focusing elements in the array 114, the size and the density of the plurality of light redirecting features 110a, 110b, 110′a, 110′b, 110″a and 110″b, the refractive indices of the material of the focusing plate 103 and the light guides 101a-101c, the vertical distances, L1, L2 and L3 between the focusing plate 103 and the plurality of light guides 101a-101c, etc. Based on the various factors, different implementations of the light collector 600 can be configured to collect light in an angular range between about 0 degrees and about 85 degrees with respect to the optical axis of the focusing elements with an efficiency of about 30% to about 60%. In various implementations, additional light guides can be disposed rearward of the light guide 101c to increase the angular range and/or the collection efficiency.

Although, in the illustrated implementation light guide 101a includes light redirecting features that are aligned with respect to the optical axis 603 and light guide 101b and 101c includes light redirecting features that are offset with respect to the optical axis 603, in various implementations, each of the plurality of light guides 101a-101c can include a first set of light redirecting features that are aligned with respect to the optical axis 603 and a second set of light redirecting features that are offset with respect to the optical axis 603. In various implementations, each of the plurality of light guides 101a-101c can include light redirecting features with different geometries and orientations so as to collect light efficiently in a wide range of angles.

FIG. 6B illustrates an implementation of a light collector 650 including a focusing plate 103 having an array of focusing elements 114 disposed on a forward (or upper) surface of the focusing plate and at least one light guide 101 including a plurality of light redirecting features 110a and 110b. The focusing plate 103 can include a plurality of turning features 605a and 605b that are disposed on a surface of the focusing plate opposite to the surface including the array of focusing elements 114. Accordingly, in the illustrated implementation, the turning features 605a and 605b are disposed on the rearward (or lower) surface of the focusing plate 103. In various implementations, the turning features 605a and 605b can be wedge shaped including a sloping surface 607 that subtends a wedge angle α respect to the rearward (or lower) surface of the focusing plate 103. In various implementations, the wedge angle α can be between about 2-60 degrees. The turning features 605a and 605b can have a transverse size D3 that can be between 0.1 mm and 10.0 mm. The turning features 605a and 605b can be offset with respect to optical axis 603 of the corresponding focusing element as illustrated in the implementation 650. In various implementations, the offset distance can be between 1.0 mm and 10.0 mm. In various implementations, the turning features 605a and 605b can be aligned with respect to the optical axis 603 of a corresponding focusing element such that light incident at oblique angles is focused by the focusing element toward the turning features 605a and 605b.

In various implementations, the plurality of light redirecting features 110a and 110b can be aligned with respect to the optical axis 603 of the corresponding focusing element in the array 114, as illustrated. In some implementations, the plurality of light redirecting features 110a and 110b can be offset with respect to the optical axis 603 of the corresponding focusing element in the array 114, as discussed above. The plurality of PV cells 105 is disposed along one or more edges of the light guide 101. The light guide 101 can be separated from the focusing plate 103 by a gap 601. In various implementations, the gap 601 can include a material having a refractive index lower than the refractive indices of the focusing plate 103 and the light guide 101. The light guide 101 is disposed rearward of the focusing plate at a vertical distance of L4. In various implementations, the vertical distance, L4, can be selected such that plurality of light redirecting features 110a, and 110b are within a distance Δf of the focal length f of each focusing element in the array 114. In various implementations, Δf can be between about 1%-10% the focal length f. In various implementations, the vertical distance between the light guide 101 and the focusing plate 103, L3 can be between 1.0 mm and 10.0 mm.

In various implementations, the size, shape and position of the plurality of light redirecting features 110a and 110b can be configured such that light incident in the angular range between approximately 0 degrees and approximately 60 degrees with respect to the optical axis 603 is redirected by the redirecting features 110a and 110b and propagates by total internal reflection toward the PV cells 105. For example, in the illustrated implementation, ray of light 615 that is incident along a direction parallel to the optical axis 603 is focused toward the toward the light redirecting features 110a and 110b such that it is turned by the light redirecting features 110a and 110b and guided by total internal reflection in the first light guide 101a.

Light that is incident on the array of focusing elements 114 at oblique angles with respect to the optical axis 603 is focused by the array of focusing elements 114 such that it is incident on the turning features 605a and 605b at an angle θ with respect to a normal to the sloping surface 607. In various implementations, the angle θ can be in the range from about 30 degrees to about 80 degrees. Light incident on the turning features 605a and 605b is refracted out of the focusing plate 103 such that it is incident on a light redirecting feature 110a and 110b. The position and size of the turning features 605a and 605b is configured such that light that refracts out of the focusing plate 103 is redirected by the redirecting feature on which it is incident and guided within the light guide 101 toward the plurality of PV cells 105.

For example, ray 625 which is incident at an oblique angle between about 20 degrees and about 70 degrees with respect to the optical axis 603 is refracted by the turning feature 605a such that it is incident on the light redirecting feature 110a and turned by the redirecting feature 110a into a guided mode of the light guide 101. In this manner the implementation 650 can be used to collect solar light that is incident in a wide range of angles (for example, between about 0 degrees and about 70 degrees with respect to the optical axis 603).

The angular range over which incident light is collected by the implementation 650 can depend on various factors including but not limited to the focal length of the focusing elements in the array 114, the size and the density of the plurality of light redirecting features 110a and 110b, the refractive indices of the material of the focusing plate 103 and the light guide 101a, the size and the density of the turning features 605a and 605b and the refractive index of the material included in the gap 601 vertical distances. Based on the various factors, different implementations of the light collector 650 can be configured to collect light in an angular range between about 0 degrees and about 85 degrees with respect to the optical axis of the focusing elements with an efficiency of about 30% to about 60%. In various implementations, additional light guides can be disposed rearward of the light guide 101a to increase the angular range and/or the collection efficiency.

As discussed above, as the earth rotates, the incident angle of sunlight on an implementation of the light collector 100 will change and thus can affect the light diverting efficiency. FIGS. 7A and 7B illustrate the effect of a change in the incidence angle of sunlight due to the earth's rotation on the light diverting efficiency of an implementation of a light collector 100.

When the sun is overhead, for example, in the noon, the sun light is incident at near normal angles on the array of focusing elements 114 of the light collector 100 and is focused on the plurality of light redirecting features 110 of the light guide 101 as illustrated in FIG. 7A. As the position of the sun moves across the sky during the course of the day, the angle of incidence deviates from the normal direction with respect to the focusing elements and thus only a portion of the focused light is incident on the plurality of optical features 110 as illustrated in FIG. 7B. Accordingly, the amount of incident radiation diverted towards the PV cell 105 can vary depending on the time of the day. In various implementations, it may be desirable to have light collectors 100 that can track and/or compensate for the diurnal movement of the sun to increase the amount of light diverted towards the PV cell 105. The light collector implementations illustrated in FIGS. 2A-4B are configured to efficiently collect and divert light that is received at different incident angles by the shape of the lenses 204a-204c. Thus, the implementations illustrated in FIGS. 2A-4B can be referred to as passively tracking or compensating for the diurnal movement of the position of the sun. The implementations of light collectors discussed below with reference to FIGS. 9A-10 are configured to efficiently collect and direct light that is received at different incident angles by mechanically moving different portions of the light collector 100 or 200. Accordingly, the implementations discussed below with reference to FIGS. 9A-10 can be referred to as being able to actively track, or compensate for, the diurnal movement of the position of the sun.

To compensate for the movement of the sun relative to a fixed location on earth, either the focusing plate 103 (or the focusing plate 201) or the light guide 101 (or the light guide 205) can be moved horizontally or vertically, relative to each other, such that the focused light beam from the focusing lenses is incident on the plurality of light redirecting features 110 (or the plurality of light redirecting elements 207a-207c). FIGS. 7A1-7B2 are simulation results showing the effect of the relative horizontal or vertical movement of different portions of an implementation of the light collector 100 illustrated in FIG. 1. For the purpose of the simulation, an implementation of a light collector having a focusing plate 103 including an array of focusing elements 114 with 100% fill factor (for example, the entire surface area of the focusing plate 103 being covered by focusing elements 114) was used.

FIGS. 8A1 and 8A2 illustrate the simulation results when sunlight is incident at an angle of about 32 degrees with respect to a normal to the forward surface of the focusing plate 103 and when each of the plurality of light redirecting features 110 is aligned with the optical axis of a corresponding focusing element in the array 114. FIG. 8A2 is an expanded view of FIG. 8A1. It can be observed from FIGS. 8A1 and 8A2 that most of the oblique incident rays focused by the array of focusing elements 114 are not directed onto the plurality of light redirecting features 110 and are thus not diverted towards the PV cell 105 disposed at the edges of the light guide 101. Accordingly, the light diverting efficiency is substantially small (for example, the simulated light diverting efficiency is approximately 0.8% for the simulated implementation of FIGS. 8A1 and 8A2).

FIGS. 8B1 and 8B2 illustrate the simulation results when sunlight is incident at an angle of about 32 degrees with respect to a normal to the forward surface of the focusing plate 103 and when the light guide 101 is horizontally moved by about 10 mm with respect to the focusing plate 103 such that each of the plurality of light redirecting features 110 is offset with respect to the optical axis of a corresponding focusing element in the array 114. FIG. 8B2 is an expanded view of FIG. 8B1. It is observed from FIGS. 8B1 and 8B2 that allowing for a lateral dislocation of about 10 mm results in the focused light striking the light redirectors. The simulated light diverting efficiency for the simulated implementation of FIGS. 8B1 and 8B2 is about 8%.

Considering these simulation results, various implementations where the focusing plate 103 (or the focusing plate 201) and/or the light guide 101 (or the light guide 105) can be moved either horizontally or vertically to change the distance or alignment between the focusing plate 103 (or the focusing plate 201) and/or the light guide 101 (or the light guide 105) can facilitate maintaining a more uniform light diverting efficiency through-out the day. Also, having a light collector that can move the focusing plate relative to the light guide vertically and/or horizontally allows some control over the amount of light that is transmitted through the solar collector.

FIGS. 9A-9C illustrate different implementations of a light collector 900 including a focusing plate 103 and a light guide 101 that can be moved horizontally or vertically with respect to each other to maintain uniform light diverting efficiency through-out the day and/or to transmit a certain amount of incident light through the light collector 900. As discussed above, horizontally moving the light guide 101 or the focusing plate 103 relative to each other can increase the light diverting efficiency by changing the horizontal position along the light guide 101 where the focused light from the focusing plate 103 strikes the light guide 101. Vertically moving the light guide 101 or the focusing plate 103 relative to each other can increase the light diverting efficiency by changing the vertical position where the light from the focusing plate 103 is focused in the light guide 101. The relative horizontal or vertical movement between the focusing plate 103 (or the focusing plate 201) and the light guide 101 (or the light guide 105) can be effected by one or more actuators 920a, 920b and 920c. The actuators 920a, 920b and 920c can be configured to horizontally or vertically move the light guide 101, the focusing plate 103 or both to maintain uniform light diverting efficiency through-out the day and/or to transmit a certain amount of incident light through the light collector 900. The actuators 920a-920c can be adapted to displace the light guide 101 by a distance of approximately 0.01 mm-1 cm horizontally and vertically relative to the focusing plate 103.

The implementation illustrated in FIG. 9A is configured to horizontally and/or vertically move the light guide 101 relative to the focusing plate 103. Actuators 920a and 920b are connected to the light guide 101 and can move the light guide 101 either alone or the light guide 101 and the PV cells 105a and 105b together along a vertical direction relative to the focusing plate 103. Actuator 920c is connected to the light guide 101 and configured to move the light guide 101 either alone or the light guide 101 and the PV cells 105a and 105b together along a horizontal direction relative to the focusing plate 103.

The implementation illustrated in FIG. 9B is configured to vertically move the light guide 101 relative to the focusing plate 103 and horizontally move the focusing plate 103 relative to the light guide 101. As discussed above, actuators 920a and 920b are connected to the light guide 101 and can move the light guide 101 either alone or the light guide 101 and the PV cells 105a and 105b together along a vertical direction relative to the focusing plate 103. Actuator 920c is connected to the focusing plate 103 and configured to move the focusing plate 103 along a horizontal direction relative to the light guide 101.

The implementation illustrated in FIG. 9C is configured to horizontally and/or vertically move the focusing plate 103 relative to the light guide 101. Actuators 920a and 920b are connected to the focusing plate 103 and can move the focusing plate 103 along a vertical direction relative to the light guide 101. Actuator 920c is also connected to the focusing plate 103 and is configured to move the focusing plate 103 along a horizontal direction relative to the light guide 101.

In various implementations, the actuators 920a, 920b and 920c can include a stepping motor and screw system, a linear electric motor, or a motor and gear system, a piezo-electric actuator, etc. In some implementations, the focusing plate 103 and the light guide 101 can be attached with leaf springs to allow relative movement.

FIG. 10 illustrates an implementation of a light collector 1000 that can actively track the movement of the sun across the sky. The implementation illustrated in FIG. 10 includes an optical element 1020 disposed between the focusing plate 103 and the light guide 101. The optical element 1020 can include lenticular, prismatic, surface or volume refractive/diffractive features 1025 that can effect a change in the direction of the focused light exiting the focusing plate 103. The optical element 1020 can be horizontally or vertically moved by actuators 920a and 920c such that the focused light strikes one of the plurality of light redirecting features 110 included in the light guide 101. In some implementations, the diffractive element 1020 can be moved along with a movement in the focusing plate 103, the light guide 101 or both. In various implementations, the optical element 1020 can effect a change in the distance where light is focused by the focusing plate 103. This can be useful in accounting for the field curvature in those implementations where the locus of the focal point lies on a curve instead of a plane.

In various implementations described in FIGS. 9A-10, the actuators 920a-920c can be electrically controlled. In such implementations, the electrical output of the one or more PV cells 105 can be monitored to generate a control signal that can control the actuators 920a-920c. The control signal can be generated by a feedback control element. For example, in some implementations, the movement of the focusing plate 103, the light guide 101 or the diffractive element 1020 can be controlled such that the amount of light diverted to the one or more PV cell 105 (in other words, the electrical output of the PV cell 105) is maximized. In some implementations, the amount of light transmitted through the light collectors 900 and 1000 can be monitored to generate a control signal that can control the actuators 920a-920c. For example, the actuators 920a-920c can be controlled such that the amount of light transmitted through the light collectors 900 and 1000 is maximized, minimized or maintained at a certain level. In various implementations, the actuators 920a-920c can be controlled such that about 20%-80% of the incident ambient light is transmitted through the light collectors 900 and 1000.

FIGS. 11A and 11B are flow charts illustrating two different examples of a method of manufacturing an implementation of a light collecting device similar to the implementations 100, 200, 600, 650, 900 and 1000 described above. Referring to FIG. 11A, the method 1100 includes providing a cylindrical-lens array having half-cylinder shaped lenses as shown in block 1110. The cylindrical-lens array can be similar to the focusing plate 201 discussed above. The cylindrical-lens array includes a top surface for receiving incident light and a bottom surface opposite the top surface. The half-cylinder-shaped lenses can be disposed on the top surface, the bottom surface or in the volume of the cylindrical-lens array. Each of the half-cylinder shaped lenses is characterized by a focal length F. The bottom surface of the cylindrical-lens array is disposed at a distance less than the focal length F such that the half-cylinder-shaped lenses directs light out of the bottom surface. In various implementations, the plurality of half-cylinder shaped lenses can be laterally spaced apart to define one or more lens spacings LS.

The method 1100 further includes disposing a light guide including a plurality of grooves as shown in block 1115. The light guide can be similar to the light guide 205 discussed above. The light guide has a top surface adjacent the bottom surface of the cylindrical-lens array and a bottom surface opposite the top surface of the light guide. The light guide includes a plurality of grooves oriented in the same longitudinal direction as the half-cylinder shaped lenses and disposed along the top surface or the bottom surface of the light guide. Each groove has a depth dimension that extends into the bottom surface of the light guide. Each groove defines at least one surface angled to redirect a portion of the focused light from the half-cylinder shaped lenses to one or more edges of the light guide. In various implementations, the plurality of grooves can be laterally spaced apart to define one or more groove spacings GS. The plurality of grooves is disposed at a distance D from the half-cylinder shaped lenses relative to a focal length of the half-cylinder shaped lenses. The lens spacings LS, the groove spacings GS and the distance D are selected such that about 20% to about 80% of light that enters the light collecting device is transmitted through the light collecting device and propagates out of the bottom surface of the light guide. The method 1000 further includes disposing at least one photocell along the one or more edges of the light guide as shown in block 1020. In various implementations, the method 1100 can include providing a space between the cylindrical-lens array and the light guide as shown in block 1130. The space can include a material having a refractive index lower than the refractive index of the light guide.

Referring to FIG. 11B, the method 1150 includes providing a lens array having a plurality of focusing elements as shown in block 1155. The lens array can be similar to the focusing plate 103 discussed above. The method 1150 further includes disposing a light guide including a plurality of light redirectors as shown in block 1160. The light guide can be similar to the light guide 101 discussed above. The lens array is disposed such that ambient light is incident on the light collecting device is incident on a top surface of the lens array and is focused by the plurality of focusing elements on to the light guide. The method 1150 further includes disposing at least one photocell along the one or more edges of the light guide as shown in block 1165. In various implementations, the method 1150 can include providing a space between the lens array and the light guide as shown in block 1170. The space can include a material having a refractive index lower than the refractive index of the light guide. The method 1150 further includes providing at least one actuator coupled to the lens array or the light guide as shown in block 1175. The actuator is configured to vertically or horizontally move the lens array or the light guide to change the position that light focused by the lens array is incident on the light guide.

Various implementations of light collectors described herein to efficiently collect, concentrate and direct light to a PV cell can be used to provide solar cells that have increased photovoltaic conversion efficiency. The light collectors can be relatively inexpensive, thin and lightweight compared to some conventional solar cells. The solar cells including light collectors described herein and coupled to one or more PV cells may be arranged to form panels of solar cells. Such panels of solar cells can be used in a variety of applications. For example, as described above, implementations of light collectors described herein coupled to one or more PV cells can be configured as building-integrated photovoltaic products such as, for example, windows, roofs, skylights, facades, etc. to generate electrical power. In other applications, implementations of light collectors described herein coupled to one or more PV cells may be mounted on automobiles and laptops to provide electrical power. Panels of solar cells including implementations of light collectors described herein coupled to one or more PV cells may be mounted on various transportation vehicles, such as aircrafts, trucks, trains, bicycles, boats, etc. Panels of solar cells including implementations of light collectors described herein coupled to one or more PV cells may be mounted on satellites and spacecrafts as well. Implementations of light collectors described herein coupled to one or more PV cells may be attached to articles of clothing or shoes.

Implementations of light collectors 100, 200, 600, 650, 800 and 900 discussed above including a plurality of focusing elements and a plurality of light redirecting features that are optically coupled to PV cells may have an added advantage of being modular. For example, depending on the design, the PV cells may be configured to be removably attached to the hybrid light collecting structures. Thus existing PV cells can be replaced periodically with newer and more efficient PV cells without having to replace the entire system. This ability to replace PV cells may reduce the cost of maintenance and upgrades substantially.

A wide variety of other variations are also possible. Films, layers, components, and/or elements may be added, removed, or rearranged. Additionally, processing operations may be added, removed, or reordered. Also, although the terms film and layer have been used herein, such terms as used herein include film stacks and multilayers. Such film stacks and multilayers may be adhered to other structures using adhesive or may be formed on other structures using deposition or in other manners.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A light collecting device, comprising:
a cylindrical-lens array including a top surface for receiving incident light and a bottom surface opposite the top surface, the cylindrical-lens array having half-cylinder-shaped lenses aligned on the top surface to collect incident light, each of the half-cylinder-shaped lenses is characterized by a focal length F, the bottom surface of the cylindrical-lens array being disposed at a distance less than the focal length F such that the half-cylinder-shaped lenses directs light out of the bottom surface; and
a light guide having a top surface adjacent the bottom surface of the cylindrical-lens array and a bottom surface opposite the top surface of the light guide, the light guide including a plurality of grooves oriented in the same longitudinal direction as the half-cylinder shaped lenses and disposed along the bottom surface of the light guide, each groove having a depth dimension that extends into the bottom surface of the light guide and each groove defining at least one surface angled to redirect a portion of the focused light from the half-cylinder shaped lenses to one or more edges of the light guide,
wherein the light collecting device is configured such that about 20% to about 80% of light that enters the top surface of the cylindrical-lens array propagates through the light collecting device and out of the bottom surface of the light guide.

2. The device of claim 1, wherein the focal length F is between about 5 mm and about 20 mm.

3. The device of claim 1, wherein the distance between two consecutive grooves is between about 2 mm and 40 mm.

4. The device of claim 1, wherein a transverse size of each half-cylinder shaped lens is between about 2 mm and about 10 mm.

5. The light collecting device of claim 1, further comprising at least one photovoltaic cell disposed along one or more edges of the light guide.

6. The light collector device of claim 1, wherein at least two of the half-cylinder-shaped lenses are laterally spaced apart by a first spacing distance.

7. The light collector device of claim 6, wherein at least two of the half-cylinder-shaped lenses are laterally spaced apart by a second spacing distance, the second spacing distance being different from the first spacing distance.

8. The light collector device of claim 7, wherein the first spacing distance is between about 0.1 mm and 25 mm and the second spacing distance is between about 0.1 mm and 100 mm.

9. The light collector device of claim 6, wherein the first spacing distance is the same for at least two pairs of adjacent half-cylinder shaped lenses in the cylindrical-lens array.

10. The light collector device of claim 6, wherein the first spacing distance is between about 0.1 mm and 100 mm.

11. The light collector device of claim 6, wherein the at least two half-cylinder-shaped lenses are characterized by a transversal size, wherein the first spacing distance is less than the transversal size.

12. The device of claim 1, wherein each of the plurality of grooves is vertically aligned with a center portion of one of the half-cylinder shaped lens.

13. The device of claim 1, wherein a set of at least two or more grooves are vertically aligned with a center portion of one of the half-cylinder shaped lenses such that light focused by the one half-cylinder shaped lens is incident on the at least two or more grooves and redirected by the at least two or more grooves towards the at least one photovoltaic cell.

14. The device of claim 1, wherein the apex of the grooves are vertically offset by approximately 0.1 mm to 5 mm from the focus of the plurality of half-cylinder shaped lenses.

15. The device of claim 1, wherein the plurality of grooves are spaced apart by a first gap of between about 0.1 mm and 200 mm.

16. The device of claim 1, wherein a set of the plurality of grooves are offset with respect to an optical axis of corresponding half-cylinder shaped lenses.

17. The device of claim 1, wherein at least two adjacent grooves are spaced apart by a first gap and at least two adjacent grooves are spaced apart by a second gap different from the first gap.

18. The device of claim 1, wherein each of the plurality of grooves includes two or more turning features.

19. The device of claim 18, wherein the turning features include at least one of: prismatic features, holographic features, diffractive features, refractive features, reflective features and scattering features.

20. The device of claim 1, wherein each of the plurality of grooves includes two or more grooves.

21. The device of claim 1, wherein the light guide has a refractive index characteristic greater than a refractive index of the cylindrical lens-array.

22. The device of claim 1, further comprising a substance having a refractive index lower than a refractive index of the light guide, the substance sandwiched between cylindrical-lens array and the light guide.

23. The device of claim 1, further comprising a gap between the light guide and the cylindrical-lens array.

24. The device of claim 23, wherein an amount of light transmitted through the light collecting device can be selected by selecting a height of the gap.

25. The device of claim 1, configured as a window of a building.

26. A light collecting device, comprising:
a plurality of means for focusing incident light configured in an array plate, each of focusing means characterized by a focal length F such that the focusing means half-directs light out of a bottom surface of the array plate; and
means for guiding light disposed adjacent to the bottom surface of the array plate, the light guiding means including means for redirecting light oriented in the same longitudinal direction as the focusing means and disposed along a bottom surface of the guiding means,
wherein the light collecting device is configured such that about 20% to about 80% of light that enters plurality of focusing means propagates through the light collecting device and out of the bottom surface of the light guiding means.

27. The light collecting device of claim 26, further comprising at least one photovoltaic cell disposed along one or more edges of the light guiding means.

28. The light collecting device of claim 26, wherein the plurality of focusing means includes a plurality of half-cylinder-shaped lenses.

29. The light collector device of claim 26, wherein the light guiding means comprises a light guide having a top surface adjacent the bottom surface of the cylindrical-lens array and a bottom surface opposite the top surface of the light guide, and wherein the light redirecting means comprises a plurality of grooves oriented in the same longitudinal direction as the half-cylinder shaped lenses and disposed along the bottom surface of the light guide, each groove having a depth dimension that extends into the bottom surface of the light guide and each groove defining at least one surface angled to redirect a portion of the focused light from the half-cylinder shaped lenses to one or more edges of the light guide.

30. A method of manufacturing a light collecting device, the method comprising:
providing a cylindrical-lens array including a top surface for receiving incident light and a bottom surface opposite the top surface, the cylindrical-lens array having half-cylinder-shaped lenses aligned on the top surface to collect incident light, each of the half-cylinder-shaped lenses is characterized by a focal length F, the bottom surface of the cylindrical-lens array being disposed at a distance less than the focal length F such that the half-cylinder-shaped lenses directs light out of the bottom surface; and
disposing a light guide having a top surface adjacent the bottom surface of the cylindrical-lens array and a bottom surface opposite the top surface of the light guide, the light guide including a plurality of grooves oriented in the same longitudinal direction as the half-cylinder shaped lenses and disposed along the bottom surface of the light guide, each groove having a depth dimension that extends into the bottom surface of the light guide and each groove defining at least one surface angled to redirect a portion of the focused light from the half-cylinder shaped lenses to one or more edges of the light guide,
wherein the plurality of half-cylinder shaped lenses are disposed laterally spaced apart to define one or more lens spacings LS, the plurality of grooves are disposed laterally spaced apart to define one or more groove spacings GS, and the plurality of grooves are disposed at a distance D from the half-cylinder shaped lenses relative to a focal length of the half-cylinder shaped lenses, and the lens spacings LS, the groove spacings GS and the distance D are selected such that about 20% to about 80% of light that enters the light collecting device is transmitted through the light collecting device and propagates out of the bottom surface of the light guide.

31. The method of claim 30, further comprising providing a space between the cylindrical-lens array and the light guide.

32. The method of claim 31, further comprising providing a material having a lower refractive index than the refractive index of the light guide in the space.

33. The method of claim 30, further comprising disposing at least one photovoltaic cell along one or more edges of the light guide.
